(19) United States
(12) Patent Application Publication
(10) Pub. No.: US 2024/0290754 A1
(43) Pub. Date: Aug. 29, 2024

(54) SEMICONDUCTOR PACKAGE

(71) Applicant: SAMSUNG ELECTRONICS CO, LTD., Suwon-si (KR)

(72) Inventors: Yu-Duk KIM, Suwon-si (KR); Hyeongmun KANG, Suwon-si (KR); Insup SHIN, Suwon-si (KR); Gunho CHANG, Suwon-si (KR)

(73) Assignee: SAMSUNG ELECTRONICS CO, LTD., Suwon-si (KR)

(21) Appl. No.: 18/433,075

(22) Filed: Feb. 5, 2024

(30) Foreign Application Priority Data
Feb. 24, 2023 (KR) 10-2023-0025011

(51) Int. Cl. H01L 25/065; H01L 23/00; H01L 23/48

(52) U.S. Cl. CPC H01L 25/0657; H01L 23/481; H01L 24/16; H01L 24/32; H01L 24/73; H01L 2224/16148; H01L 2224/16227; H01L 2224/32145; H01L 2224/32225; H01L 2224/73204; H01L 2225/06513; H01L 2225/06517; H01L 2225/06541; H01L 2225/06555; H01L 2924/1431; H01L 2924/1436; H01L 2924/182

(57) ABSTRACT

Provided is a semiconductor package including a first semiconductor chip, a plurality of second semiconductor chips on the first semiconductor chip, and a dummy chip on the plurality of second semiconductor chips, wherein each of the plurality of second semiconductor chips has a first width, and wherein the dummy chip has a second width smaller than the first width.

### CROSS-REFERENCE TO RELATED APPLICATIONS

This application claims priority to Korean Patent Application No. 10-2023-0025011, filed on Feb. 24, 2023, in the Korean Intellectual Property Office, the disclosure of which is incorporated by reference herein in its entirety.

### BACKGROUND

Embodiments of the present disclosure relate to semiconductor package.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. With the development of electronic industry, various studies are underway to improve compatibility and increase operating speeds of semiconductor packages.

### SUMMARY

One or more embodiments provide a semiconductor package with improved reliability.

According to an aspect of an embodiment, there is provided a semiconductor package including a first semiconductor chip, a plurality of second semiconductor chips on the first semiconductor chip, and a dummy chip on the plurality of second semiconductor chips, wherein each of the plurality of second semiconductor chips has a first width, and wherein the dummy chip has a second width smaller than the first width.

According to another aspect of an embodiment, there is provided a semiconductor package including a first semiconductor chip, a plurality of second semiconductor chips on the first semiconductor chip, and a dummy chip on the plurality of second semiconductor chips, wherein each of the plurality of second semiconductor chips has a first thickness, and wherein the dummy chip has a second thickness greater than the first thickness.

According to another aspect of an embodiment, there is provided a semiconductor package including a first semiconductor chip, a plurality of second semiconductor chips on the first semiconductor chip, a first underfill layer between the first semiconductor chip and a lowermost second semiconductor chip among the plurality of second semiconductor chips, a second underfill layer between adjacent second semiconductor chips among the plurality of second semiconductor chips, a dummy chip on the plurality of second semiconductor chips, a third underfill layer between an uppermost second semiconductor chip among the plurality of second semiconductor chips and the dummy chip, and a mold layer on the first semiconductor chip, the plurality of second semiconductor chips, and the dummy chip, wherein each of the first semiconductor chip and the plurality of second semiconductor chips includes a substrate including a rear surface and a front surface that are opposite to each other, a plurality of frontside conductive pads on the front surface, a plurality of backside conductive pads on the rear surface, a plurality of through via penetrating the substrate and on each of the plurality of backside conductive pads, respectively, and a plurality of first internal connection members on the plurality of frontside conductive pads, respectively, wherein the dummy chip includes a plurality of second internal connection members on a lower surface of the dummy chip and in the third underfill layer, wherein each of the plurality of second semiconductor chips has a first width and a first thickness, wherein the dummy chip has a second width smaller than the first width and a second thickness greater than the first thickness, wherein the second width is 0.1 to 0.9 times the first width, and wherein the second thickness is 1 to 3 times the first thickness.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor package according to embodiments;

FIG. 2 is a cross-sectional view of the semiconductor package of FIG. 1 taken along the line I-I′;

FIG. 3 is an enlarged view illustrating a second semiconductor chip of the semiconductor package of FIG. 2;

FIG. 4 is a cross-sectional view of the semiconductor package of FIG. 1 taken along the line I-I′;

FIGS. 5A, 5B, 5C, 5D, 5E, and 5G are cross-sectional views sequentially illustrating a process of manufacturing the semiconductor package of FIG. 4;

FIG. 6 is a cross-sectional view illustrating a semiconductor package according to embodiments; and

FIG. 7 is a cross-sectional view illustrating a semiconductor package according to embodiments.

### DETAILED DESCRIPTION

Hereinafter, embodiments according to the present disclosure will be described in more detail with reference to the accompanying drawings.

Embodiments described herein are example embodiments, and thus, the disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

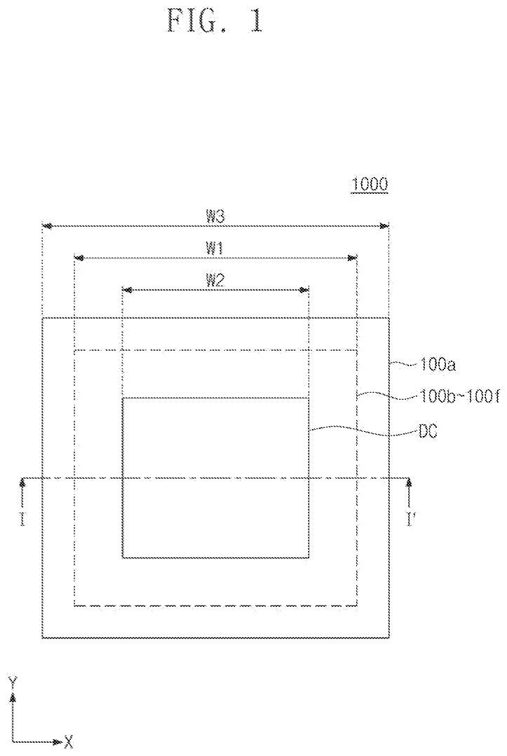

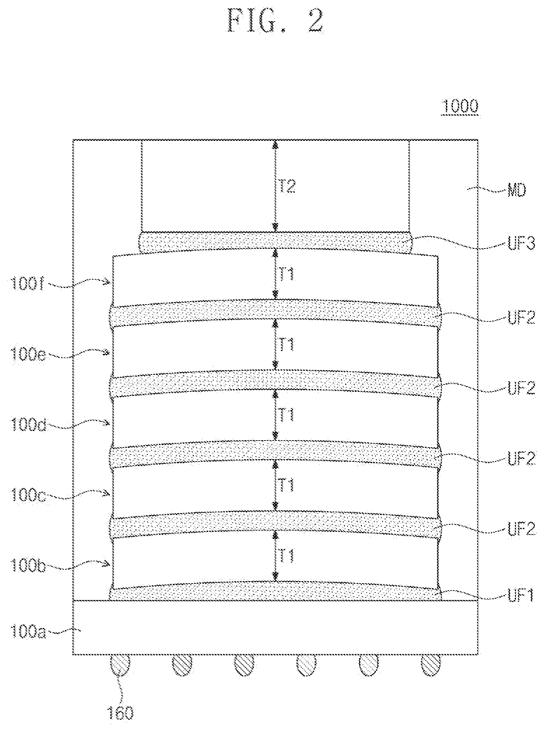

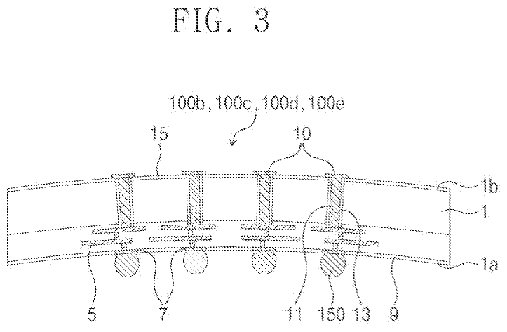

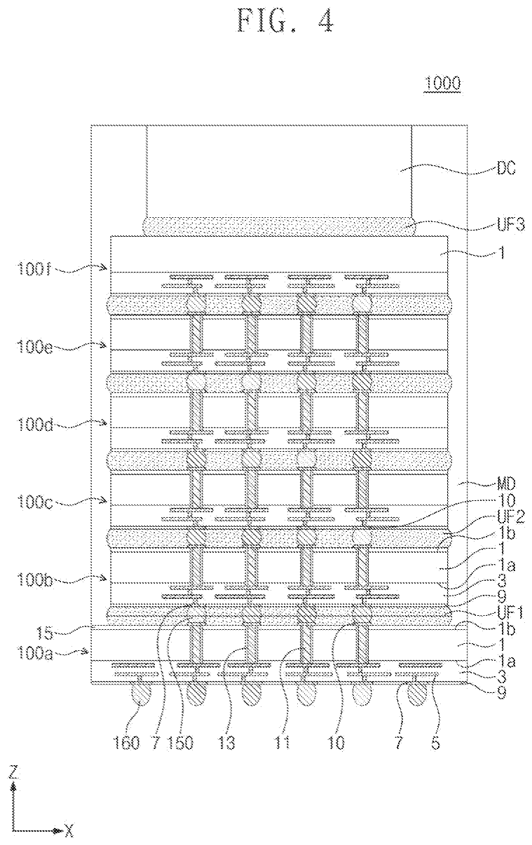

FIG. 1 is a plan view illustrating a semiconductor package according to embodiments, FIG. 2 is a cross-sectional view of the semiconductor package of FIG. 1 taken along the line I-I′, FIG. 3 is an enlarged view illustrating a second semiconductor chip of the semiconductor package of FIG. 2, and FIG. 4 is a cross-sectional view of the semiconductor package of FIG. 1 taken along the line I-I′.

Referring to FIGS. 1 to 4, a semiconductor package 1000 according to an embodiment includes a first semiconductor chip 100a, second semiconductor chips 100b, 100c, 100d, 100e, and 100f, and a dummy chip DC which are sequentially stacked and a mold layer MD covering the first semiconductor chip 100a and the second semiconductor chips 100b, 100c, 100d, 100e, and 100f.

The second semiconductor chips 100b to 100f may be disposed (stacked) on the first semiconductor chip 100a. A first underfill layer UF1 may be interposed between the first semiconductor chip 100a and a lowermost second semiconductor chip 100b among the second semiconductor chips 100b to 100f.

A width of the first semiconductor chip 100a may be wider than a width of each of the second semiconductor chips 100b to 100f. For example, the second semiconductor chips 100b to 100f have the same first width W1 in a horizontal direction, and the first semiconductor chip 100a has a third width W3 greater than the first width W1 in the horizontal direction.

The first semiconductor chip 100a may be a different type of chip from the second semiconductor chips 100b to 100f. The first semiconductor chip 100a may be, for example, a logic circuit chip. The second semiconductor chips 100b to 100f may be the same memory chips (e.g., DRAM chips). Although FIG. 2 illustrates a structure in which one logic circuit chip and five memory chips are disposed, the number of disposed logic circuit chips and memory chips may be various, and embodiments are not limited thereto. The semiconductor package 1000 may have a high bandwidth memory (HBM) chip structure.

As shown in FIG. 4, each of the first semiconductor chip 100a and the second semiconductor chips 100b to 100f may include a substrate 1, an interlayer insulating layer 3, wirings 5, frontside conductive pads 7, a first passivation layer 9, and a second passivation layer 15. The substrate 1 may include a front surface 1a of the substrate 1 and a rear surface 1b of the substrate 1 that are opposite to each other. The interlayer insulating layer 3 may be disposed on the front surface 1a of the substrate. Transistors and multilayered wirings 5 may be disposed in the interlayer insulating layer 3. The interlayer insulating layer 3 may be covered with the first passivation layer 9. The frontside conductive pads 7 may be disposed under the interlayer insulating layer 3.

The rear surface 1b of the substrate 1 may be covered with the second passivation layer 15. A plurality of backside conductive pads 10 may be disposed on the second passivation layer 15.

Each of the first semiconductor chip 100a and the second semiconductor chips 100b to 100f may further include a through via 11 and a through insulating layer 13. In each of the first semiconductor chip 100a and the second semiconductor chips 100b to 100f, the through vias 11 may penetrate portions of the second passivation layer 15, the substrate 1, and the interlayer insulating layer 3. The through insulating layer 13 may be interposed between the through via 11 and the substrate 1. An upper surface of the through via 11 may be in contact with the backside conductive pad 10. A lower surface of the through via 11 may be in contact with one of the wirings 5.

External connection terminals 160 may be respectively bonded to the frontside conductive pads 7 of the first semiconductor chip 100a. First internal connection members 150 may be connected to the frontside conductive pads 7 of each of the second semiconductor chips 100b to 100f.

An uppermost second semiconductor chip 100f among the second semiconductor chips 100b to 100f may not include the through via 11 and the through insulating layer 13. Also, the uppermost second semiconductor chip 100f may not include the second passivation layer 15 and the backside conductive pads 10.

The second semiconductor chips 100b to 100f may be connected to each other by first internal connection members 150. For example, first internal connection members 150 may be disposed between adjacent second semiconductor chips among the second semiconductor chips 100b to 100f. Each of the first internal connection members 150 may connect the backside conductive pads 10 of the second semiconductor chip disposed directly below among the second semiconductor chips 100b to 100f to the frontside conductive pads of the second semiconductor chip disposed directly above. A second underfill layer UF2 may be interposed between the second semiconductor chips 100b to 100f.

The substrates 1 may be silicon substrates. For example, the substrates 1 may be silicon single crystal substrates or silicon on insulator (SOI) substrates. The interlayer insulating layers 3 may include at least one single layer or multiple layers selected from a silicon oxide layer, a silicon nitride layer, a silicon oxynitride layer, and a porous insulating layer.

The mold layer MD may cover an upper surface of the first semiconductor chip 100a and side surfaces of the second semiconductor chips 100b to 100f. The mold layer MD may include, for example, an insulating resin such as an epoxy-based molding compound (EMC). The mold layer MD may further include a filler, and the filler may be dispersed in the insulating resin. The filler may include, for example, silicon oxide (SiO₂). A first underfill layer UF1, a second underfill layer UF2, and a third underfill layer UF3 may include a thermosetting resin or a photocurable resin. Also, the first to third underfill layers UF1, UF2, and UF3 may further include an organic filler or an inorganic filler.

The frontside conductive pads 7, the backside conductive pads 10, the first internal connection members 150, the wirings 5, the through vias 11, and the external connection terminals 160 may include a conductive material, for example, metal, respectively. Each of the wirings 5 may independently include, for example, at least one of copper, tungsten, aluminum, ruthenium, titanium, tantalum, titanium nitride, and tantalum nitride. The through vias 11 may include, for example, tungsten.

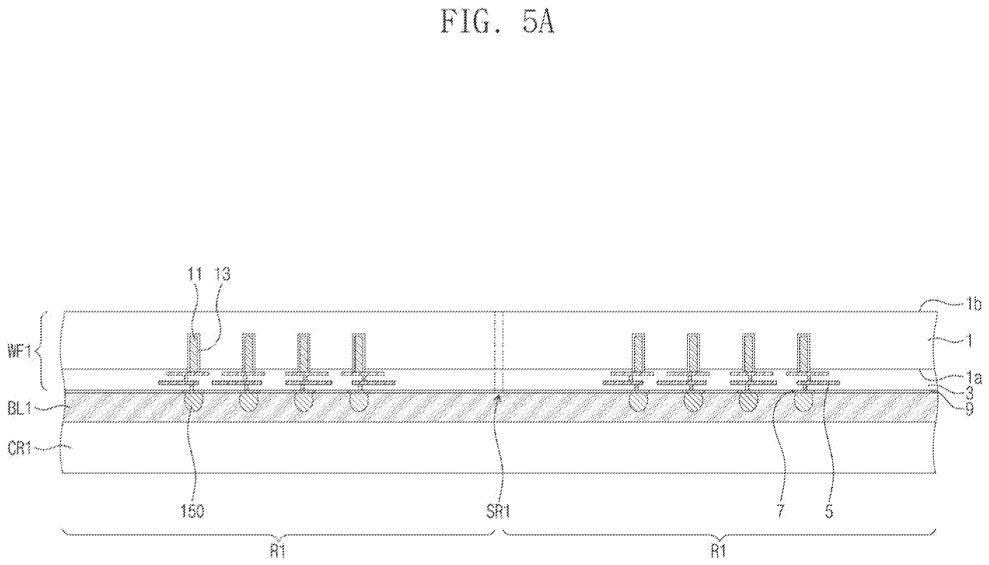

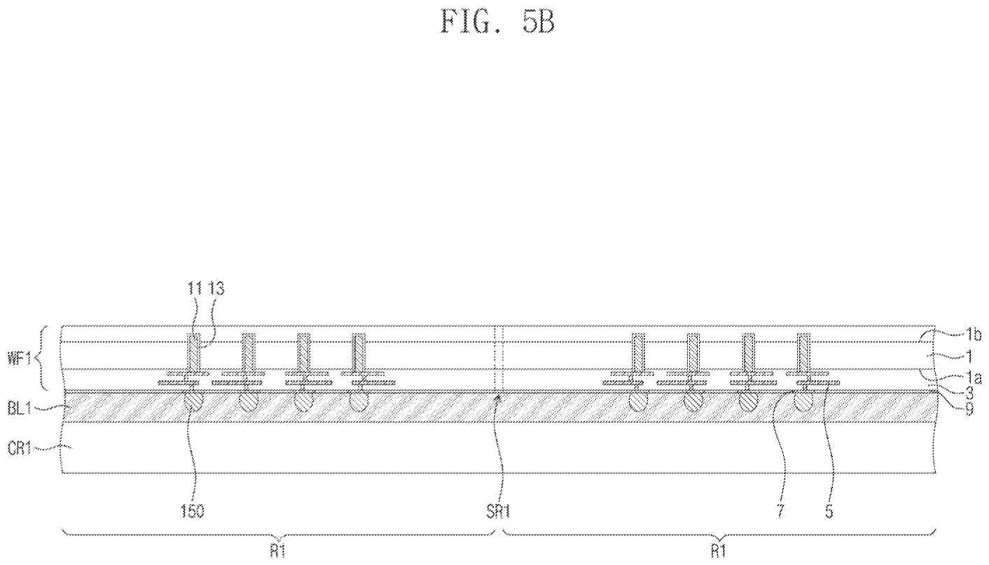

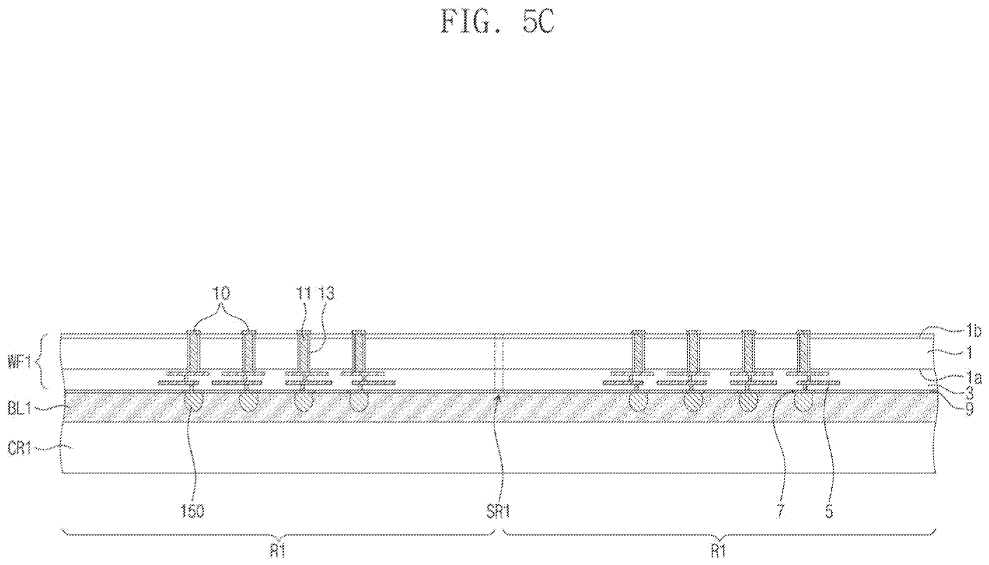

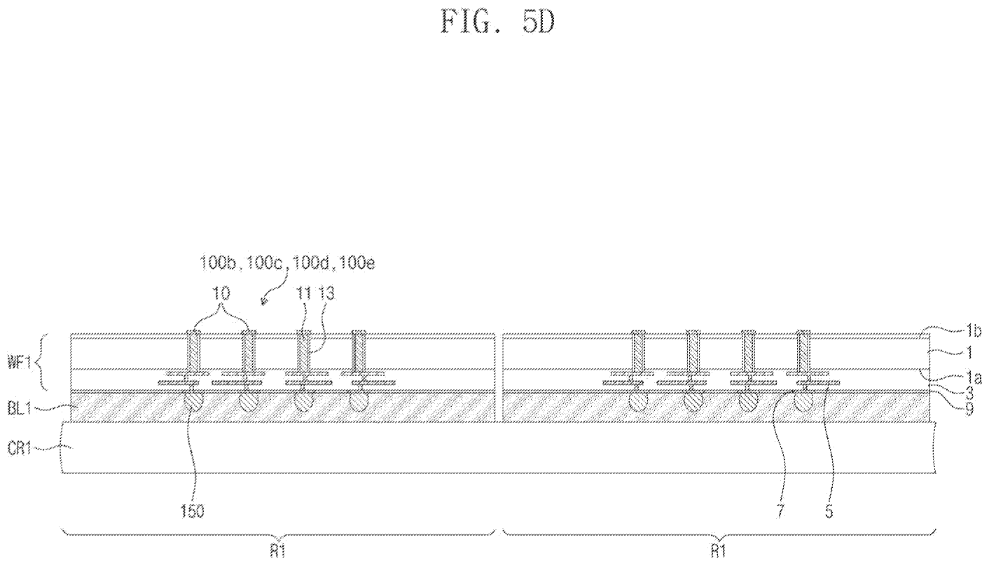

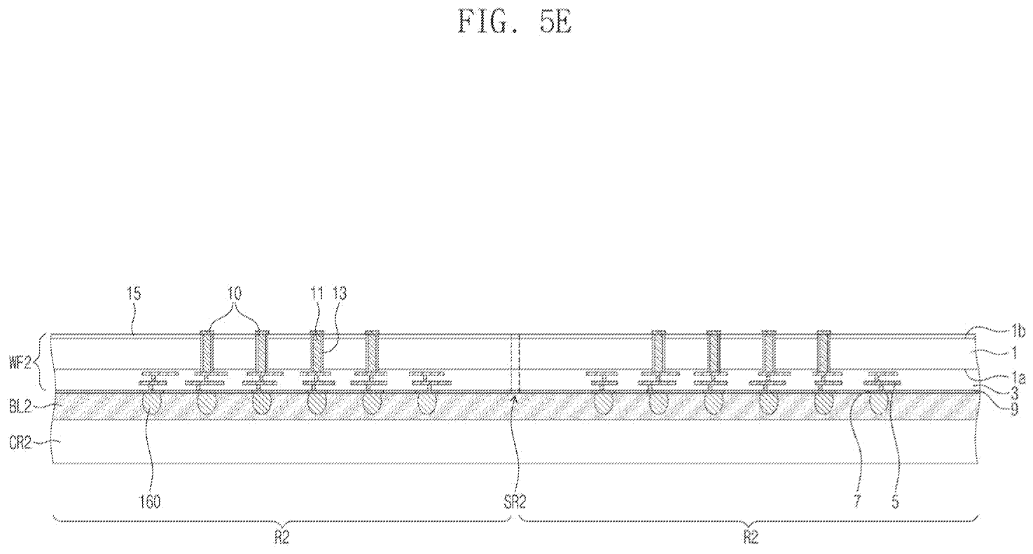

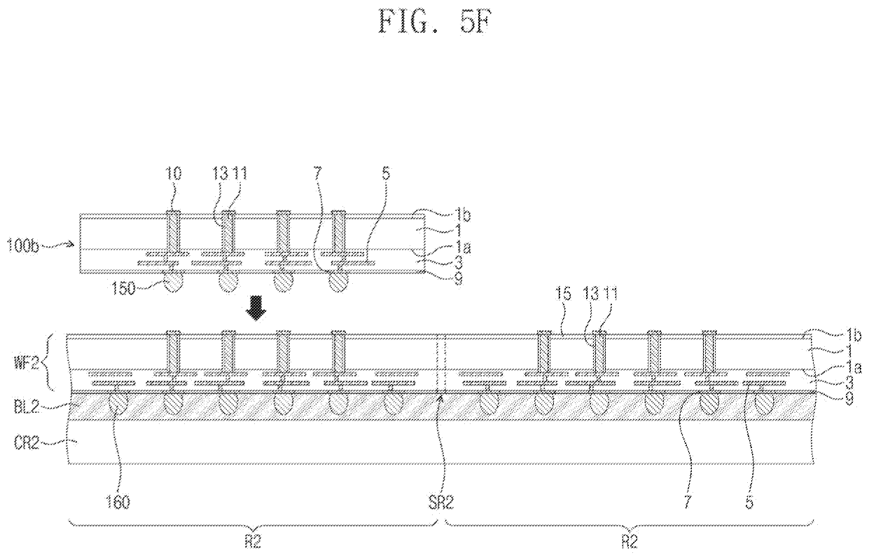

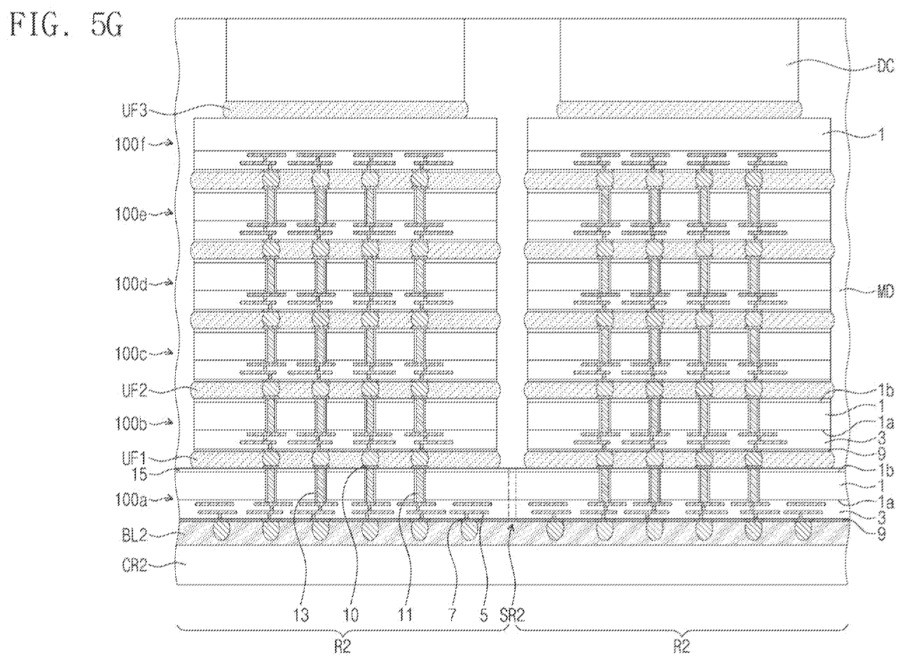

The second semiconductor chips 100b to 100f may have the same first thickness T1 in a vertical direction. As shown in FIGS. 2 and 3, the second semiconductor chips 100b to 100f may have an upward convex shape. In a manufacturing process of the semiconductor package 1000 according to an embodiment, a thermal compression process may be performed to bond the first internal connection members 150 of each of the second semiconductor chips 100b to 100f in a state FIG. 5F to the backside conductive pads 10 of the semiconductor chip disposed thereunder. The thermal compression process may be performed at, for example, a temperature of about 360 degrees or higher, and the front surface 1a of each of the second semiconductor chips 100b to 100f may be bent by the thermal compression process. Accordingly, the second semiconductor chips 100b to 100f have an upward convex shape.

In this case, the second semiconductor chips 100b to 100f may have the same first thickness T1 and thus the front surface 1a of each of the second semiconductor chips 100b to 100f may be bent to have the same curvature. Accordingly, when the second underfill layer UF2 is interposed between the adjacent second semiconductor chips 100b to 100f as shown in FIG. 2, an unfilled space may be completely filled with the underfill layer UF2 between adjacent second semiconductor chips 100b to 100f.

The dummy chip DC may be a silicon substrate. For example, the dummy chip DC may be a silicon single crystal substrate or a silicon on insulator (SOI) substrate. The dummy chip DC may be disposed on the second semiconductor chips 100b to 100f. That is, the dummy chip DC may be disposed on an uppermost second semiconductor chip 100f among the second semiconductor chips 100b to 100f. The third underfill layer UF3 may be interposed between the dummy chip DC and the uppermost second semiconductor chip 100f.

The dummy chip DC may have a second width W2 smaller than the first width W1 of each of the second semiconductor chips 100b to 100f in the first direction X. For example, the second width W2 may be 0.1 to 0.9 times the first width W1. The dummy chip DC may have a smaller width than each of the second semiconductor chips 100b to 100f and be disposed on the second semiconductor chips 100b to 100f. Accordingly, when a mold layer MD covers the dummy chip DC, the first semiconductor chip 100a, and the second semiconductor chips 100b to 100f as described above, the mold layer MD comes into contact with a side surface of the dummy chip DC, a portion of an upper surface of the uppermost second semiconductor chip 100f, and side surfaces of the second semiconductor chips 100b to 100f. Therefore, a contact area between the mold layer MD, and the dummy chip DC, the first semiconductor chip 100a, and the second semiconductor chips 100b to 100f may be increased, thereby improving adhesiveness of the mold layer MD. In addition, as an upper surface of the dummy chip DC is coplanar with an upper surface of the mold layer MD, heat generated during an operation of the semiconductor package 1000 may be discharged to the outside through the dummy chip DC, thereby improving reliability of the semiconductor package 1000.

The dummy chip DC may have a second thickness T2 different from the first thickness T1 of the second semiconductor chips 100b to 100f in the vertical direction. As illustrated, the dummy chip DC may have a second thickness T2 greater than the first thickness T1 of each of the second semiconductor chips 100b to 100f. For example, the second thickness T2 may be 1 to 3 times the first thickness T1. As the dummy chip DC is provided to have a greater thickness than each of the second semiconductor chips 100b to 100f and is disposed on the second semiconductor chips 100b to 100f, a structural stability of the semiconductor package 1000 may be improved, and a contact area with the mold layer MD may be vertically increased, thereby improving adhesiveness of the mold layer MD. The dummy chip DC may have the same thickness as the first thickness T1 of each of the second semiconductor chips 100b to 100f or may have a thickness smaller than the first thickness T1 of each of the second semiconductor chips 100b to 100f. A design of the dummy chip DC may be variously changed to determine a thickness of the semiconductor package 1000.

FIGS. 5A and 5G are cross-sectional views sequentially illustrating a process of manufacturing the semiconductor package of FIG. 4.

Referring to FIG. 5A, a first wafer structure WF1 is prepared. The first wafer structure WF1 may have a plurality of first chip regions R1 and a first separation region SR1 therebetween. The first separation region SR1 may be a scribe lane region. The first wafer structure WF1 may include a substrate 1. The substrate 1 may include a front surface 1a of the substrate 1 and a rear surface 1b of the substrate 1 that are opposite to each other. Transistors and a portion of the interlayer insulating layer 3 covering the transistors are formed on the front surface 1a of the substrate. A portion of the interlayer insulating layer 3 and the substrate 1 are etched to form a through hole, and a through via 11 and a through insulating layer 13 are formed in the through hole. Wirings 5 and an interlayer insulating layer 3 that are in contact with the through via 11 are formed. Conductive pads 7 and a passivation layer 9 are formed on the interlayer insulating layer 3. The first wafer structure WF1 may be bonded to a first carrier substrate CR1 with a first adhesive layer BL1 interposed therebetween so that the passivation layer 9 faces downward. The first adhesive layer BL1 may include an adhesive/thermosetting/thermoplastic/photocurable resin.

Referring to FIG. 5B, a grinding or etch-back process is performed on the rear surface 1b of the substrate 1 to partially remove the substrate 1 and to expose the through insulating layer 13. In this case, the rear surface 1b of the substrate 1 is lower than an end of the through via 11 in the vertical direction. For example, a thickness of the substrate 1 may be reduced through the grinding process. The through via 11 protrude from the rear surface 1b of the substrate 1. A second passivation layer 15 is formed on the rear surface 1b of the substrate 1.

Referring to FIG. 5C, at least a portion of the second passivation layer 15 and a portion of the through insulating layer 13 may be removed by a CMP or etch-back process to expose the through vias 11. Backside conductive pads 10 are formed on the second passivation layer 15. The backside conductive pads 10 may be formed by depositing and etching conductive layers. According to another embodiment, the backside conductive pads 10 may be formed through a plating process. The backside conductive pads 10 are formed to be in contact with the through vias 11.

Referring to FIG. 5D, the first separation region SR1 of the first wafer structure WF1 may be removed using a dicing process using a laser or the like to form a plurality of semiconductor chips 100b to 100e. As a result, the second semiconductor chips 100b to 100e of FIG. 4 may be formed. Subsequently, the second semiconductor chips 100b to 100e are separated from the first adhesive layer BL1.

The uppermost second semiconductor chip 100f of FIG. 4 may be formed by performing a dicing process without forming the through vias 11 and the through insulating layer 13 in the first wafer structure WF1. A grinding process for reducing the thickness of the substrate 1 in the first wafer structure WF1 may also be omitted.

Referring to FIG. 5E, a second wafer structure WF2 is prepared. The second wafer structure WF2 may have a plurality of second chip regions R2 and a second separation region SR2 therebetween. The second separation region SR2 may be a scribe lane region. The second wafer structure WF2 may include a substrate 1. Each of the second chip regions R2 may include the structure of the first semiconductor chip 100a described with reference to FIG. 1. Rear surface conductive pads 10 may be formed on the rear surface 1b of the substrate 1. External connection terminals 160 may be formed on the frontside conductive pads 7 positioned on a lower surface of the second wafer structure WF2. The second wafer structure WF2 may be bonded to the second carrier substrate CR2 via a second adhesive layer BL2. The second adhesive layer BL2 may include an adhesive/thermosetting/thermoplastic/photocurable resin.

Referring to FIG. 5F, second semiconductor chips 100b to 100f are disposed on the second chip region R2 of the second wafer structure WF2. In this case, an internal connection members 150 of the second semiconductor chip 100b are bonded to the backside conductive pads 10 of the second wafer structure WF2. A first internal connection members 150 of the second semiconductor chips 100c to 100f are bonded to the backside conductive pads 10 of the second semiconductor chips 100b to 100e positioned directly below the first internal connection members 150. In this case, the second semiconductor chips 100b to 100e may be positioned so that the through vias 11 of each of the second semiconductor chips 100b to 100e are aligned with each other.

The first internal connection members 150 of each of the second semiconductor chips 100b to 110f illustrated in FIG. 5F may be bonded with the backside conductive pads 10 of the semiconductor chip disposed thereunder using a thermal compression process. For example, the thermal compression process may be performed at a temperature of about 360 degrees or more. The front surface 1a of each of the second semiconductor chips 100b to 100f may be bent by the thermal compression process, and accordingly, each of the second semiconductor chips 100b to 100f may be formed to be convex upward.

Referring to FIG. 5G, after bonding the second semiconductor chips 100b to 100f by using the thermal compression bonding process, a dummy chip DC is bonded on the uppermost second semiconductor chip 100f with a third underfill layer UF3 interposed therebetween. Then, a dicing process using a laser may be performed to remove the second wafer structure WF2 and the mold layer MD of the second separation region SR2 to manufacture a plurality of semiconductor packages (1000 of FIG. 4). Subsequently, the semiconductor packages 1000 may be separated from the second adhesive layer BL2.

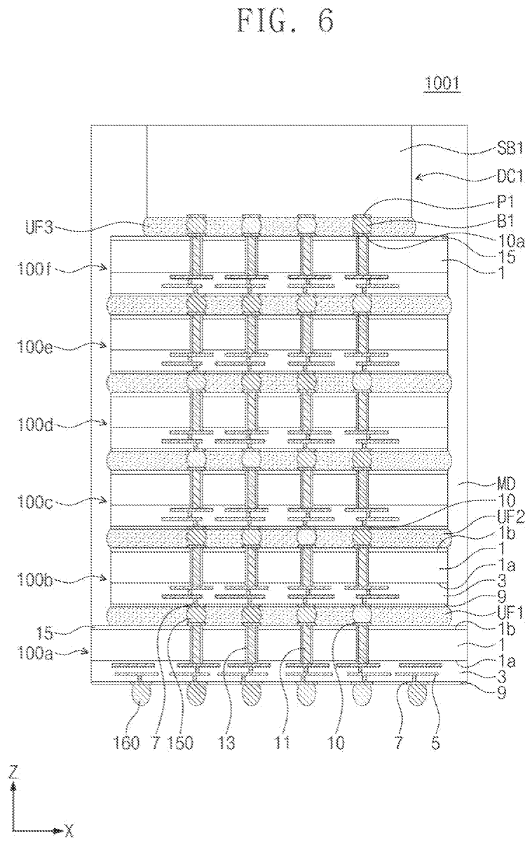

FIG. 6 is a cross-sectional view illustrating a semiconductor package according to embodiments.

Referring to FIG. 6, a semiconductor package 1001 according to an embodiment is the same as the semiconductor package 1000 described with reference to FIGS. 1 to 5G except that a dummy chip DC1 includes a second internal connection members B1, the same reference numerals are used and overlapping descriptions are omitted.

The dummy chip DC1 may include a silicon substrate SB1. For example, the dummy chip DC1 may include a silicon single crystal substrate or a silicon on insulator (SOI) substrate. The dummy chip DC1 may be disposed on the second semiconductor chips 100b to 100f. For example, the dummy chip DC1 may be disposed on the uppermost second semiconductor chip 100f among the second semiconductor chips 100b to 100f.

The dummy chip DC1 may have a second width W2 smaller than the first width W1 of the second semiconductor chips 100b to 100f in the horizontal direction. The second width W2 may be greater than a distance between the through vias 11 positioned at the edge of the uppermost second semiconductor chip 100f when viewed in a plan view. Accordingly, when the third underfill layer UF3 is interposed between the dummy chip DC1 and the uppermost second semiconductor chip 100f, the third underfill layer UF3 may completely cover the through vias 11 of the uppermost second semiconductor chip 100f to prevent upper surfaces of the through vias 11 from being exposed, thereby improving reliability of the semiconductor package 1001.

The dummy chip DC1 may include a plurality of lower surface pads P1 disposed on the lower surface, and second internal connection members B1 bonded to a plurality of lower surface pads P1. The third underfill layer UF3 may be interposed between the dummy chip DC1 and the uppermost second semiconductor chip 100f. In this case, the second internal connection members B1 of the dummy chip DC1 may be disposed within the third underfill layer UF3. The second internal connection members B1 may be bonded to the conductive pads 10a disposed on an upper surface of the uppermost second semiconductor chip 100f. The second internal connection members B1 of the dummy chip DC1 may be bonded to the upper surface of the uppermost second semiconductor chip 100f, thereby increasing adhesiveness between the dummy chip DC1 and the uppermost second semiconductor chip 100f.

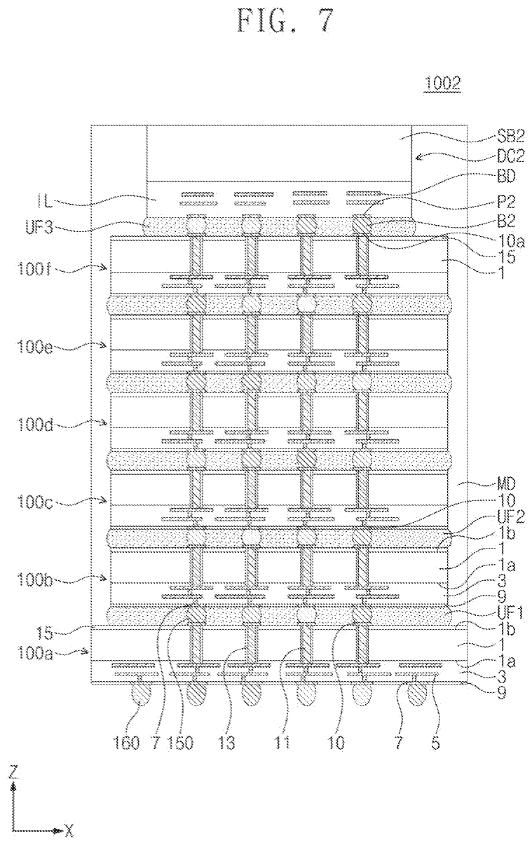

FIG. 7 is a cross-sectional view illustrating a semiconductor package according to embodiments.

Referring to FIG. 7, a semiconductor package 1002 according to an embodiment is the same as the semiconductor package 1001 described with reference to FIG. 6 except that the dummy chip DC2 further includes an interlayer insulating layer IL and a wiring layer BD, and thus the same reference numerals are used and overlapping descriptions are omitted.

The dummy chip DC2 may include a silicon substrate SB2, an interlayer insulating layer IL disposed under the silicon substrate SB2, a wiring layer BD disposed in the interlayer insulating layer IL, a plurality of lower surface pads P2 disposed on a lower surface of the interlayer insulating layer IL, and second internal connection members B2 bonded to the plurality of lower surface pads P2. The second internal connection members B2 may be bonded to the conductive pads 10a disposed on the upper surface of the uppermost second semiconductor chip 100f.

The dummy chip DC2 may have a second width W2 smaller than the first width W1 of the second semiconductor chips 100b to 100f. The second width W2 may be larger than a distance between the through vias 11 positioned at the edge of the uppermost second semiconductor chip 100f when viewed in a plan view. Accordingly, when the third underfill layer UF3 is interposed between the dummy chip DC2 and the uppermost second semiconductor chip 100f, the third underfill layer UF3 may completely cover the through vias 11 of the uppermost second semiconductor chip 100f to prevent the upper surfaces of the through vias 11 from being exposed, thereby improving reliability of the semiconductor package 1002.

In the semiconductor package according to embodiments, the plurality of second semiconductor chips disposed on the first semiconductor chip may be formed to have the same thickness, and thus the upper and lower surfaces of the second semiconductor chips may be bent with the same curvature. Accordingly, the unfilled space not being completely filled with the underfill layer between the disposed second semiconductor chips may be prevented. Accordingly, the risk of cracks between the second semiconductor chips may be reduced, and the moisture in the unfilled space that is not completely filled with the underfill layer may be prevented, thereby improving the reliability of the semiconductor package.

While example embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a first semiconductor chip;
a plurality of second semiconductor chips on the first semiconductor chip; and
a dummy chip on the plurality of second semiconductor chips,
wherein each of the plurality of second semiconductor chips has a same first width, and
wherein the dummy chip has a second width which is smaller than the first width.

2. The semiconductor package of claim 1, wherein each of the plurality of second semiconductor chips is convex upward.

3. The semiconductor package of claim 2, wherein the first semiconductor chip has a third width which is greater than the first width.

4. The semiconductor package of claim 1, wherein each of the plurality of second semiconductor chips has a same first thickness, and
wherein the dummy chip has a second thickness which is different from the first thickness.

5. The semiconductor package of claim 4, wherein the second thickness is greater than the first thickness.

6. The semiconductor package of claim 1, wherein the dummy chip comprises a silicon substrate.

7. The semiconductor package of claim 6, wherein the dummy chip further comprises:
an interlayer insulating layer under the silicon substrate; and
a wiring layer included in the interlayer insulating layer.

8. The semiconductor package of claim 1, wherein each of the first semiconductor chip and the plurality of second semiconductor chips comprises:
a substrate comprising a rear surface and a front surface that are opposite to each other;
a plurality of frontside conductive pads on the front surface;
a plurality of backside conductive pads on the rear surface;
a plurality of through-vias penetrating the substrate and on each of the plurality of backside conductive pads, respectively; and
a plurality of first internal connection members on the plurality of frontside conductive pads, respectively.

9. The semiconductor package of claim 1, further comprising:
a first underfill layer between the first semiconductor chip and a lowermost second semiconductor chip among the plurality of second semiconductor chips;
a second underfill layer between adjacent second semiconductor chips among the plurality of second semiconductor chips; and
a third underfill layer between an uppermost second semiconductor chip among the plurality of second semiconductor chips and the dummy chip.

10. The semiconductor package of claim 9, wherein the dummy chip comprises a plurality of second internal connection members on a lower surface of the dummy chip and in the third underfill layer.

11. The semiconductor package of claim 1, wherein the dummy chip comprises:
a silicon substrate;
an interlayer insulating layer under the silicon substrate;
a wiring layer in the interlayer insulating layer;
a plurality of lower surface pads on a lower surface of the interlayer insulating layer; and
a plurality of second internal connection members on the plurality of lower surface pads.

12. A semiconductor package comprising:
a first semiconductor chip;
a plurality of second semiconductor chips on the first semiconductor chip; and
a dummy chip on the plurality of second semiconductor chips,
wherein each of the plurality of second semiconductor chips has a same first thickness, and
wherein the dummy chip has a second thickness which is greater than the first thickness.

13. The semiconductor package of claim 12, wherein the second thickness is 1 to 3 times the first thickness.

14. The semiconductor package of claim 12, wherein each of the plurality of second semiconductor chips have a same first width, and
wherein the dummy chip has a second width smaller than the first width.

15. The semiconductor package of claim 14, wherein the second width is 0.1 to 0.9 times the first width.

16. The semiconductor package of claim 12, wherein the dummy chip comprises a silicon substrate.

17. The semiconductor package of claim 16, wherein the dummy chip further comprises:
an interlayer insulating layer under the silicon substrate; and
a wiring layer in the interlayer insulating layer.

18. The semiconductor package of claim 12, further comprising:
a first underfill layer between the first semiconductor chip and a lowermost second semiconductor chip among the plurality of second semiconductor chips;
a second underfill layer between adjacent second semiconductor chips among the plurality of second semiconductor chips; and
a third underfill layer between an uppermost second semiconductor chip among the plurality of second semiconductor chips and the dummy chip.

19. The semiconductor package of claim 18, wherein the dummy chip comprises a plurality of second internal connection members on a lower surface of the dummy chip and in the third underfill layer.

20. A semiconductor package comprising:
a first semiconductor chip;
a plurality of second semiconductor chips on the first semiconductor chip;
a first underfill layer between the first semiconductor chip and a lowermost second semiconductor chip among the plurality of second semiconductor chips;
a second underfill layer between adjacent second semiconductor chips among the plurality of second semiconductor chips;
a dummy chip on the plurality of second semiconductor chips;
a third underfill layer between an uppermost second semiconductor chip among the plurality of second semiconductor chips and the dummy chip; and
a mold layer on the first semiconductor chip, the plurality of second semiconductor chips, and the dummy chip,
wherein each of the first semiconductor chip and the plurality of second semiconductor chips comprises:
a substrate comprising a rear surface and a front surface that are opposite to each other;
a plurality of frontside conductive pads on the front surface;
a plurality of backside conductive pads on the rear surface;
a plurality of through via penetrating the substrate and on each of the plurality of backside conductive pads, respectively; and
a plurality of first internal connection members on the plurality of frontside conductive pads, respectively,
wherein the dummy chip comprises a plurality of second internal connection members on a lower surface of the dummy chip and in the third underfill layer,
wherein each of the plurality of second semiconductor chips has a first width and a first thickness,
wherein the dummy chip has a second width smaller than the first width and a second thickness greater than the first thickness,
wherein the second width is 0.1 to 0.9 times the first width, and
wherein the second thickness is 1 to 3 times the first thickness.
